(19) United States
(12) Patent Application Publication
(10) Pub. No.: US 2014/0133105 A1
(43) Pub. Date: May 15, 2014

(54) METHOD OF EMBEDDING CPU/GPU/LOGIC CHIP INTO A SUBSTRATE OF A PACKAGE-ON-PACKAGE STRUCTURE

(71) Applicant: NVIDIA CORPORATION, Santa Clara, CA (US)

(72) Inventors: Abraham F. Yee, Cupertino, CA (US); Jayprakash Chipalkatti, Cupertino, CA (US); Shantanu Kalchuri, San Jose, CA (US)

(73) Assignee: NVIDIA CORPORATION, Santa Clara, CA (US)

(21) Appl. No.: 13/673,280

(22) Filed: Nov. 9, 2012

(51) Int. Cl. H05K 7/06; H05K 7/20

(52) U.S. Cl. CPC H05K 7/06; H05K 7/20509; H05K 7/205
USPC 361/720; 361/764

(57) ABSTRACT

Embodiments of the invention provide an IC system in which low-power chips can be positioned proximate high-power chips without suffering the effects of overheating. In one embodiment, the IC system may include a first substrate, a high-power chip embedded within the first substrate, a second substrate disposed on a first side of the first substrate, the first substrate and the second substrate are in electrical communication with each other, and a low-power chip disposed on the second substrate. In various embodiments, a heat distribution layer is disposed adjacent to the high-power chip such that the heat generated by the high-power chip can be effectively dissipated into an underlying printed circuit board attached to the first substrate, thereby preventing heat transfer from the high-power chip to the low-power chip. Therefore, the lifetime of the low-power chip is extended.

### BACKGROUND OF THE INVENTION

1. Field of the Invention

Embodiments of the present invention generally relate to integrated circuit chip packaging and, more specifically, to a package-on-package (POP) packaging system with a high power chip and a low power chip.

2. Description of the Related Art

With the development of the electronics industry, there are increasing demands for smaller electronic devices with improved performance. In order to achieve a higher integration density and a smaller footprint of electronic components, a so-called “package-on-package (POP)” technology has been developed. POP is a three-dimensional packaging technology used to vertically stack a plurality of leadframe-based semiconductor packages atop each other with an interface to route signals between them.

Minimizing the thickness of the package has been a challenge to the successful implementation of the POP technology since there is generally a trade-off between the thermal management of chips and other devices contained in the package and the performance of the devices. Specifically, by locating memory chips, passive devices, and other low-power components of an IC package as close as possible to the central processor unit (CPU) and other high-power devices in an IC package, communication between devices in the IC package is accelerated and packaging parasitics are reduced. However, heat generated by higher-power chips is known to adversely affect memory chips and other devices positioned nearby. Consequently, it is not thermally feasible to stack memory chips and passive devices directly on or under a CPU or other high-power chip when incorporated into a single IC package, since such a configuration necessarily limits the power of the high-power chip or affects the performance of the memory chips.

As the foregoing illustrates, there is a need in the art for a package system having a greater density of integrated circuits with a corresponding reduction in package size. There is a further need for a high-power chip and a low-power chip arrangement in a vertical stack which prevents heat transfer between the chips.

### SUMMARY OF THE INVENTION

Embodiments of the present invention set forth an IC system in which one or more low-power chips can be positioned proximate high-power chips without suffering the effects of overheating. In one embodiment, the IC system includes a high-power chip embedded in a first packaging substrate, and a low-power chip disposed on a second packaging substrate which is positioned above the first packaging substrate to form a stack. Because portions of the first packaging substrate thermally insulate the embedded high-power chip from the low-power chip, the low-power chip can be positioned proximate the high-power chip without being overheated. In certain embodiments, a thin heat distribution layer is positioned adjacent to a side of the high-power chip to spread heat of the high-power chip into the first packaging substrate. In a molded POP packaging system, heat in the first packaging substrate is transferred through solder balls into an underlying printed circuit board (PCB), which serves as a heat sink for the IC system.

One advantage of the present invention is that a memory chip or other low-power chip can be positioned in close proximity to a high-power chip that is embedded in a packaging substrate in the same IC system without being overheated by the high-power chip. Such close proximity advantageously reduces the overall thickness of the packaging system, thus a thinner and lighter electronic device is realized. By having a heat distribution layer disposed adjacent to the high-power chip, the heat generated by the high-power chip can be effectively dissipated into the printed circuit board (PCB), which further prevents heat transfer from the high-power chip to the low-power chip. Therefore, the lifetime of the low-power chip is extended.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an integrated circuit (IC) system, according to one embodiment of the invention.

FIG. 2 is a schematic cross-sectional view of an IC system having a heat distribution mechanism disposed adjacent to a high-power chip to increase thermal transmittance from the high-power chip, according to another embodiment of the invention.

FIG. 3 is a schematic cross-sectional view of an IC system having a heat distribution mechanism disposed adjacent to a high-power chip to increase thermal transmittance from the high-power chip, according to yet another embodiment of the invention.

For clarity, identical reference numbers have been used, where applicable, to designate identical elements that are common between figures. It is contemplated that features of one embodiment may be incorporated in other embodiments without further recitation.

### DETAILED DESCRIPTION

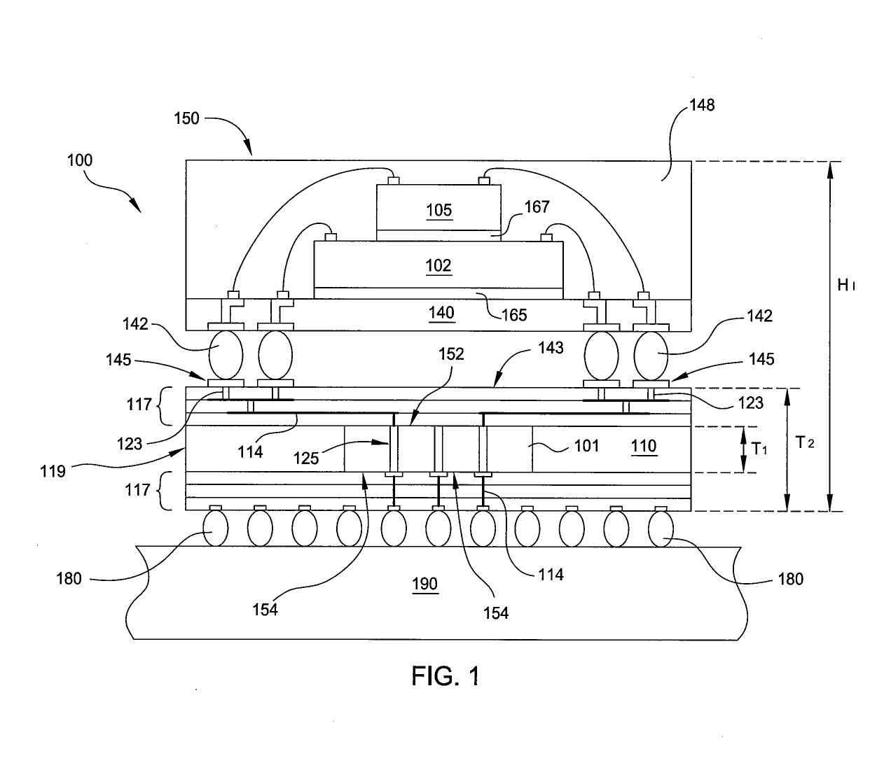

FIG. 1 is a schematic cross-sectional view of an integrated circuit (IC) system 100, according to one embodiment of the invention. The IC system 100 generally includes multiple IC chips and/or other discrete microelectronic components, and is configured to electrically and mechanically connect said chips and components to a printed circuit board 190. The IC system may be a vertical combination, i.e., a stacked configuration, of one or more high-power chips 101 and one or more low-power chips 102, 105, in which the one or more low-power chips 102, 105 are thermally insulated from the one or more high-power chips 101. Therefore, the low-power chips 102, 105 are not significantly affected by the heat originating from the high-power chips 101

In this disclosure, high-power chip 101 is a high-power processor, such as a central processing unit (CPU), a graphics processing unit (GPU), application processor or other logic device, or any IC chip capable of generating enough heat during operation to adversely affect the performance of low-power chip 101 or passive devices located in the IC system 100. For example, a high-power chip is typically one that generates at least 10 W of heat or more during normal operation. Conversely, a low-power chip is one that does not generate enough heat during operation to adversely affect the performance of adjacent IC chips or devices. For example, a low-power chip is any IC chip that generates on the order of about 1 W of heat, i.e., no more than about 5 W, during normal operation. Low-power chips may be passive devices located in the IC system 100, for example a memory device, such as RAM or flash memory, an I/O chip, or any other chip that does not generate over 5 W in normal operation.

In the embodiment shown in FIG. 1, the IC system 100 includes a high-power chip 101 embedded in a first packaging substrate 110, and a low-power chip 102 mounted on a second packaging substrate 140. The low-power chips 102 may be mounted on the second packaging substrate 140 through an electrical conductive pad 165. If a pack of low-power chips are used, the top low-power chip 105 may be mounted onto the bottom low-power chip 102 through an electrical conductive pad 167. The first packaging substrate 110 is substantially parallel to and opposing to the second packaging substrate 140. The second packaging substrate 140 is disposed over a top surface 143 of the first packaging substrate 110 and is electrically connected to the first packaging substrate 110 through electrical connections 142. The electrical connections 142 between the second packaging substrate 140 and the first packaging substrate 110 may be made using any technically feasible approach known in the art, such as a solder bump or a solder ball. The electrical connections 142 may be in physical contact with corresponding bond pads 145 formed on the top surface 143 of the first packaging substrate 110. It is contemplated that the electrical communication between the second packaging substrate 140 and the first packaging substrate 110 may also be made by other bonding techniques, such as a flip-chip bonding technique or a pin grid array (PGA) technique.

The low-power chip 102 mounted on the second packaging substrate 140 may be encapsulated in a molding material 148 to protect the low-power chips 102. If desired, reliability of electrical connections 142 may be improved by protecting the electrical connections 142 with an encapsulant material. The molding or encapsulant material may be a resin, such as epoxy resin, acrylic resin, silicone resin, polyurethane resin, polyamide resin, polyimide resin, etc. Any other technically feasible packaging techniques may be used to protect the low-power chip 102 or electrical connections 142 of the low-power chip 102 to the first packaging substrate 110. While not shown, it is contemplated that the top side 150 of the molding material 148 facing away from the second packaging substrate 140 may be attached to a heat sink or other cooling mechanism to enhance the thermal transmittance of the IC system 100.

The low-power chip 102 is mounted opposite the high-power chip 101 in a stacked configuration, and is electrically connected to the high-power chip 101 and the PCB 190 via conductive traces 114 and conductive vias 123 formed in the first packaging substrate 110. The electrical connection between the high-power chip 101 and the first packaging substrate 110 may be made using any technically feasible approach known in the art. It is noted that conductive traces 114 and conductive vias 123, and configuration thereof, are exemplary approaches that can be used to electrically connect the high-power chip 101 to external components. Any known electrical connection with a different routing arrangement/configuration may be used in lieu of or in addition to the use of conductive traces 114 and conductive vias 123.

In the embodiment illustrated in FIG. 1, the high-power chip 101 includes through-silicon vias (TSVs) 125, which run through the high-power chip 101 and serve as power, ground, and signal interconnections throughout the high-power chip 101. TSVs 125 is configured to facilitate fast electrical connections between the high-power chip 101 and the first packaging substrate 110, which in turn, facilitate electrical connections between the high-power chip 101, the low-power chip 102, and the PCB 190. As opposed to wire-bonding technique where the electrical connections, such as bond pads and the like, are manufactured on a single side of the high-power chip and thick metal wires are used to interconnect the bond pads to external circuitry, TSVs 125 can make electrical connections to components on both sides of the high-power chip 102. With TSVs 125, the high-power chip 101 can be embedded in the IC system 100 as shown in FIG. 1 and enables electrical connections of the high-power chip 101 to both the low-power chip 102 (through conductive traces 114, conductive vias 123, and electrical connections 142) and to the PCB 190 (through a plurality of packaging leads 180). Therefore, a very short path-length interconnect between the high-power chip 101 and the low-power chip 102 is obtained.

Shorter routing of interconnects between circuits results in faster signal propagation and reduction in noise, cross-talk, and other parasitics. In the field of IC packaging, parasitics are caused by the interconnection of a chip to external components, e.g., IC bond pads, bond wires, package leads, conductive traces, and the like. By stacking low-power chip 102 and high-power chip 101 in an overlapping configuration as illustrated in FIG. 1, the length of interconnects between low-power chip 102 and high-power chip 101 is minimized, and such parasitics are greatly reduced. Further, the overall “footprint” of IC system 100 is minimized as compared to an IC package in which high-power chip 101 and low-power chip 102 are positioned side-by-side on the same side of a packaging substrate. In addition, embedding the high-power chip 101 in the first packaging substrate 110 reduces the thickness “H₁” of the IC system 100 by at least about 25 μm or more, as compared to the existing POP packaging system where the high-power chip is mounted on the top surface 143 of the first packaging substrate 110. Most importantly, since the high-power chip 101 is closer to the PCB 190 (which serves as a heat sink for the IC system 100) and portions of first packaging substrate 110 can act as a thermally insulating layer, the low-power chip 102 is thermally insulated from the embedded high-power chip 101 without being adversely affected by the heat generated by the high-power chip 101.

The first packaging substrate 110 provides the IC system 100 with structural rigidity and an electrical interface for routing input and output signals as well as power between the high-power chip 101, the low-power chip 102, and the PCB 190. The first packaging substrate 110 may be a laminate substrate comprised of a stack of insulation layers 117 or laminates that are built up on the top surface 152 and bottom surface 154 of a core layer 119 in which the high-power chip 101 is embedded. The conductive traces 114 and the conductive vias 123 are formed between the insulation layers 117 to provide electrical communication between the high-power chip 101, the low-power chip 102, and the PCB 190. The high-power chip 101 can be embedded in the first packaging substrate 110 by forming a cavity or recessed opening in the core layer 119 using a wet or dry etching process. The cavity or recessed opening is sized for accommodation of the high-power chip 101. After the high-power chip 101 is formed in the core layer 119, the insulation layers 117 and electrical connections such as the conductive traces 114 and the conductive vias 123 are then formed around the high-power chip 101. While not discussed herein, it should be appreciated by a skilled artisan that the conductive traces 114 may be formed by any suitable process such as etching a copper foil bonded to one or more laminates of the first packaging substrate 110. The conductive vias 123 may be a copper-filled vias formed by electroplating process or any other suitable technique.

The high-power chip 101 may be located at a pre-determined depth in the first packaging substrate 110. It may be advantageous in some embodiments to place the high-power chip 101 at an elevation that is closer to the PCB 190 to promote heat dissipation into the PCB 190. It is also contemplated that the high-power chip 101 may not need to be fully embedded in the first packaging substrate 110. The top surface 152 of the high-power chip 101 may be flush with, slightly below or above the top surface 143 of the first packaging substrate 110. The elevation of the high-power chip 101 may vary depending upon the process scheme or application. In one embodiment, the high-power chip 101 may have a thickness “T₁” of about 100 μm to about 200 μm, for example about 150 μm. The first packaging substrate 110 may have a thickness “T₂” of about 300 μm to about 500 μm, such as about 400 μm. A thicker or thinner profile is contemplated depending upon application.

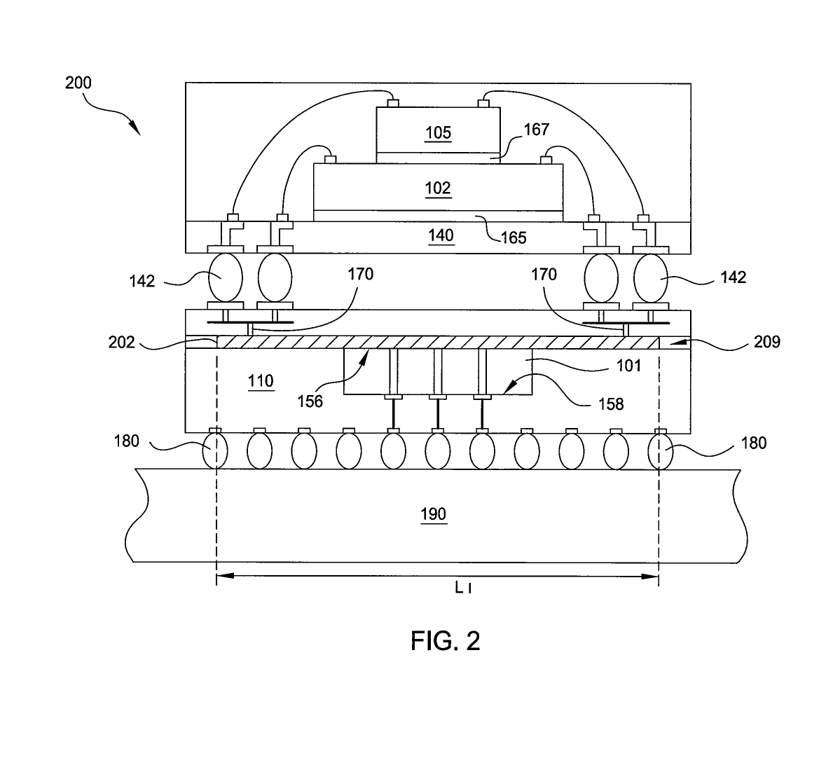

FIG. 2 is a schematic cross-sectional view of an IC system 200 having a heat distribution mechanism disposed adjacent to a high-power chip to increase thermal transmittance from the high-power chip, according to another embodiment of the invention. It is noted that the electrical connections such as the conductive traces 114 and the conductive vias 123 shown in FIG. 1 have been simplified and labeled as 170, or simply omitted for ease of understanding. The IC system 200 is substantially similar in configuration and operation to the IC system 100, except that a heat distribution layer 202 is embedded in the first packaging substrate 110. In the embodiment as shown, the heat distribution layer 202 is formed as a layer 209 in the first packaging substrate 110 and is positioned in physical contact with a top surface 156 of the high-power chip 101 to promote fast heat dissipation from the high-power chip 101 to the first packaging substrate 110. Alternatively, the heat distribution layer 202 may be separated from the high-power chip 101 by a distance. The heat distribution layer 202 may be in a form of a metal sheet having a higher thermal conductivity than the first packaging substrate 110. In one embodiment, the heat distribution layer 202 is comprised of copper or another electrical conductive material, such as aluminum, gold, silver, or alloys of two or more elements. The heat distribution layer 202 may be bonded to the top surface 156 of the high-power chip 101 using a conductive adhesive layer (not shown) made of a conductive resin or paste, to ensure good heat conduction and secured attachment to the high-power chip 101.

The heat distribution layer 202 is configured to conduct thermal energy generated by the high-power chip 101 away from the low-power chip 102, thereby reducing the risk of overheating the low-power chip 102 during operation of IC system. The heat distribution layer 102 distributes the heat into, and throughout the first packaging substrate 202 along the longitudinal direction of the first packaging substrate 110. The heat is then dissipated to the PCB 190 through the packaging leads 180. Due to the increased surface area of the heat distribution layer 202 within the first packaging substrate 110 for heat dissipation, thermal energy generated by the high-power chip 101 can be dissipated into the PCB 190 more efficiently.

The heat distribution layer 202 may be laterally extended in a plane parallel to the top surface 156 of the first packaging substrate 110. The heat distribution layer 202 may be formed using an electroplating process, a physical vapor deposition (PVD), or any other suitable deposition process during the fabrication of the first packaging substrate 110. The heat distribution layer 202 may have a length “L₁” slightly shorter than the length of the first packaging substrate 110, but longer than the length of the high-power chip 101. In one example, the length “L₁” of the heat distribution layer 202 is between about 20 μm and about 150 μm, for example, about 80 μm. While only one heat distribution layer 202 is shown, it is contemplated that two or more heat distribution layers may be used in the first packaging substrate 110 in any suitable arrangement to enhance heat removal from the high-power chip 101. For example, two or more heat distribution layers (not shown) may be attached to the bottom surface 158 of the high-power chip 101, with or without the heat distribution layer 202 attached to the top surface 156 of the high-power chip 101. Any additional heat distribution layer (if used) may extend laterally through the first packaging substrate 110 along a longitudinal direction of the first packaging substrate 110, or in any other arrangement depending upon the application. In some embodiments, the heat distribution layer 202 and/or any additional heat distribution layer (if used) may be formed from two or more layers of metallic foil, and the thickness of which can be readily determined by one of skill in the art given the footprint of the IC system 200 and the heat generation of the high-power chip 101 and the low-power chip 102. While not shown, it is contemplated that the heat distribution layer 202 may include through-holes to allow interconnects to run between the low-power chip 102 and the high-power chip 101 without contacting the heat distribution layer 202.

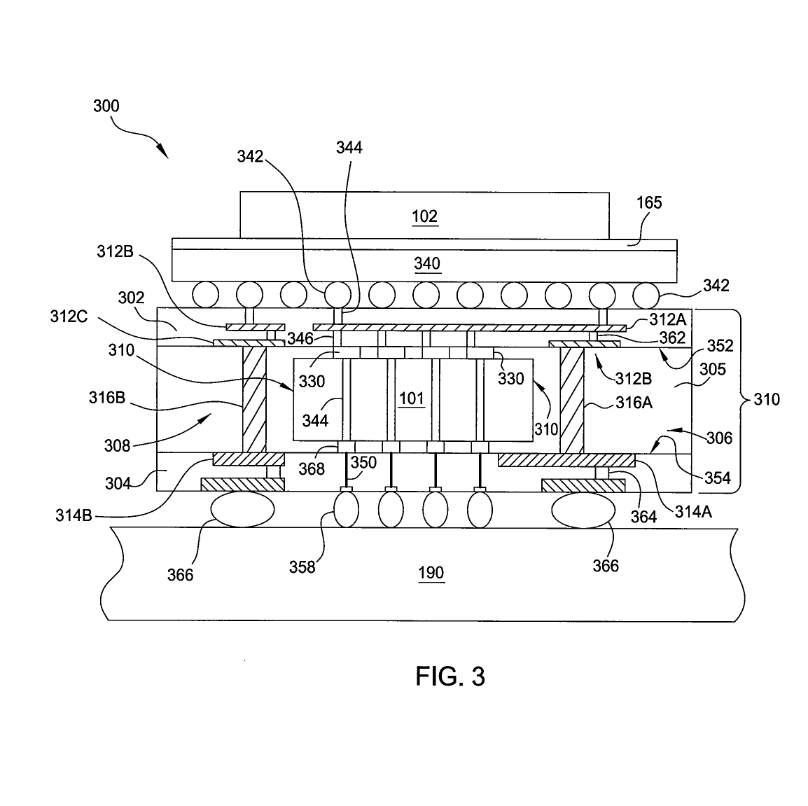

FIG. 3 is a schematic cross-sectional view of an IC system 300 having a heat distribution mechanism disposed adjacent to a high-power chip to increase thermal transmittance from the high-power chip, according to yet another embodiment of the invention. The IC system 300 is similar in configuration and operation to the IC system 100, except that the high-power chip 101 is encapsulated in a molding material 305 which is sandwiched between a top insulation layer 302 and a bottom insulation layer 304.

The high-power chip 101 is embedded within a first supporting substrate 310. The first supporting substrate 310 is comprised of the top insulation layer 302, the bottom insulation layer 304, and the molding material 305 sandwiched between the top insulation layer 302 and the bottom insulation layer 304. The molding material 305 encapsulates the high-power chip 101. Specifically, the molding material 305 substantially fills the spaces 306, 308 defined by the top insulation layer 302, the bottom insulation layer 304, and periphery 310 of the high-power chip 101, resulting in the high-power chip 101 surrounded by the molding material 305. While not shown, the top and bottom insulation layers 302, 304 may be a laminate structure comprised of a stack of insulation layers (such as the insulation layers 117 shown in FIG. 1), or laminates that are built up on the top surface 352 and bottom surface 354 of the molding material 305 in which the high-power chip 101 is encapsulated. The top and bottom insulation layers 302, 304 and the molding material 305 (encapsulating the high-power chip 101) thus form the first supporting substrate 310 with functionality similar to the first packaging substrate 110 shown in FIG. 1.

The bottom surface 354 of the molding material 305 may be substantially co-planar with the top surface of the bottom insulation layer 304, while the top surface 352 of the molding material 305 may be substantially co-planar with the bottom surface of the top insulation layer 302. In such a case, the high-power chip 101 may be separated from the top insulation layer 302 and/or the bottom insulation layer 304 by a desired distance. Alternatively, the top insulation layer 302 may be a continuous layer covering the top surface 352 of the molding material 305 and the top surface of the high-power chip 101 that is embedded within the molding material 305, while the bottom insulation layer 304 may be a continuous layer covering the bottom surface 354 of the molding material 305 and the bottom surface of the high-power chip 101 that is embedded within the molding material 305. In either case, the molding material 305 may include any suitable molding material known in the art that flows well and therefore minimizes the formation of any gaps. In one example, the molding material is a molding compound such as epoxy resin, acrylic resin, silicone resin, polyurethane resin, polyamide resin, polyimide resin, etc.

The top insulation layer 302 may include a top redistribution feature embedded therein to facilitate routing of electrical signals between the low-power chip 102, the high-power chip 101, and the PCB 190. In one embodiment, the top redistribution feature is an electrical conductive wire 312a laterally extended a desired length in a plane parallel to the top surface 352 of the molding material 305. In another embodiment, the top redistribution feature may include two or more electrical conductive wires (either coplanar or non coplanar wires) arranged in the top insulation layer 302 and electrically connected in a parallel relationship with each other by conductive vias 362. The use of the redistribution feature enables a reduction in the number of routing layers in the first supporting substrate 310 for the package system 300. FIG. 3 shows one exemplary arrangement where coplanar electrical conductive wires 312a, 312b are electrically connected to underlying, coplanar electrical conductive wires 312d, 312c, respectively. The top redistribution feature may also serve to spread the heat generated by the high-power chip 101 into the top insulation layer 302. It is contemplated that the arrangement and the number of the first redistribution feature may vary depending upon the external connections, the dimension of the top insulation layer 302, and the application. In various embodiments, the top redistribution feature is comprised of copper or another conductive material, such as aluminum, gold, silver, or alloys of two or more elements.

The electrical connections between the low-power chip 102, the high-power chip 101, and the PCB 190 can be made by any technically feasible chip package electrical connection known in the art. In one embodiment, the one or more top redistribution features 312a may connect respectively to solder bumps 342 and one or more bond pads 330 disposed on one side of the high-power chip 101 through conductive vias 344 and conductive vias 346, respectively. The one or more bond pads 330 are in electrical communication with one or more bond pads 368 disposed on the other side of the high-power chip 101 by means of through-silicon vias 344 formed through the high-power chip 101. Similarly, the one or more bond pads 368 are in electrical communication with the PCB 190 through conductive lines 350 and BGA 358. While not discussed herein, it is contemplated that the same electrical connections may be used to transmit power, ground and/or I/O signal between the low-power chip 102, the high-power chip 101, and the PCB 190.

Similarly, the bottom insulation layer 304 may include a bottom redistribution feature embedded therein to facilitate routing of electrical signals between the low-power chip 102, the high-power chip 101, and the PCB 190, thereby enabling a reduction in the number of routing layers in the first supporting substrate 310 for the package system 300. The bottom redistribution feature may be an electrical conductive wire 314a laterally extended a desired length in a plane parallel to the bottom surface 354 of the molding material 305. Alternatively, the bottom redistribution feature may include two or more electrical conductive wires (either coplanar or non coplanar wires) arranged in the bottom insulation layer 304 and electrically connected in a parallel relationship with each other by conductive vias 364, thereby enabling a reduction in the number of routing layers in the first supporting substrate 310 for the package system 300. The bottom redistribution feature may also serve to spread the heat generated by the high-power chip 101 into the bottom insulation layer 304. While not shown, it is contemplated that the top and bottom insulation layers 302, 304 may include one or more electrical traces, bond pad connectors, vias, wires, or any known structure, construction, arrangement in the art for physically transferring a signal or power from one point in a circuit to another. The top and bottom redistribution features may also be in any other arrangement/configuration that would increase thermal transmittance from the high-power chips 101 into the first supporting substrate 310.

With the top and bottom insulation layers 302, 304 and associated redistribution features embedded therein, the high-power chip 101 can be in electrical communication with the low-power chip 102 mounted on a second supporting substrate 340 (identical in structure and operation to the second packaging substrate 140 in FIG. 1) and the PCB 190. To facilitate heat dissipation from the high-power chip 101 to the first supporting substrate 310 and therefore to the PCB 190, a set of heat distribution feature may be formed in the molding material 305 on both sides of the high-power chip 101. In the embodiment shown in FIG. 3, two heat distribution features 316a, 316b are shown. However, fewer or more heat distribution features are contemplated. The heat distribution features 316a, 316b may run vertically through the molding material 305 to electrically and thermally connect the top insulation layer 302 and the bottom insulation layer 304. Specifically, the heat distribution features 316a, 316b are in physical contact with the top redistribution feature, e.g., electrical conductive wires 312d, 312c, and the bottom redistribution feature, e.g., electrical conductive wires 314a, 314b, respectively. Therefore, heat absorbed by the top insulation layer 302 can be transmitted through the set of heat distribution features 316 to the bottom insulation layer 304, and then to the PCB 190 through packaging leads or electrical conductive mechanisms such as C4 bumps 366. The PCB 190, as discussed above, serves as a heat sink for the IC system 300. Due to the increased surface area of the set of heat distribution features 316a, 316b in the first supporting substrate 310 for heat dissipation, thermal energy generated by the high-power chip 101 can be dissipated into the PCB 190 more efficiently.

The set of heat distribution features may be thermal conductive vias formed by laser drilling or any other suitable technique. The thermal conductive vias is filled with a heat transmit media using any suitable technique such as an electroplating process. In one example, the thermal conductive vias is filled with a metal filler such as copper. However, any material with higher thermal conductivity than the first supporting substrate 310 may be used.

With the inventive configuration of the heat distribution features, the low-power chips 102 are not suffering the effects of overheating since the high-power chip 101 is embedded in the packaging substrate and the heat generated by the high-power chip 101 can be effectively dissipated into the PCB 190 through the heat distribution layer 202 as shown in FIG. 2, or the set of heat distribution features 316, 318 as shown in FIG. 3.

In sum, embodiments of the invention set forth an IC system in which one or more low-power chips can be positioned proximate high-power chips without suffering the effects of overheating. By having a heat distribution feature disposed adjacent to the one or more high-power chips embedded in a packaging substrate, the heat generated by the high-power chips can be effectively dissipated into the packaging substrate and then to a PCB, which serves as a heat sink for the IC system, thereby preventing heat transfer from the high-power chips to the low-power chips. As a result, the lifetime of the memory chip is extended.

While the foregoing is directed to embodiments of the present invention, other and further embodiments of the invention may be devised without departing from the basic scope thereof, and the scope thereof is determined by the claims that follow.

We claim:

1. A integrated circuit system, comprising:
a first substrate;
a high-power chip embedded within the first substrate;
a second substrate disposed adjacent to a first side of the first substrate, wherein the first substrate and the second substrate are in electrical communication with each other; and
a low-power chip disposed on the second substrate.

2. The system of claim 1, further comprising:
a heat distribution layer embedded within the first substrate, wherein the heat distribution layer extends laterally along a longitudinal direction of the high-power chip.

3. The system of claim 2, wherein the heat distribution layer has a length longer than a length of the high-power chip.

4. The system of claim 2, wherein the heat distribution layer is positioned adjacent to the high-power chip.

5. The system of claim 2, wherein the heat distribution layer is attached to at least a first side of the high-power chip.

6. The system of claim 2, wherein the heat distribution layer is made of an electrical conductive material comprising copper, aluminum, gold, silver, or alloys of two or more electrical conductive elements.

7. The system of claim 1, further comprising:
a printed circuit board disposed adjacent to a second side of the first substrate, wherein the second side is parallel to and opposing the first side of the first substrate.

8. The system of claim 7, wherein the high-power chip is electrically connected to the first substrate by a plurality of electrical conductive vias formed through the high-power chip.

9. The system of claim 8, wherein the high-power chip is in thermal and electrical communication with the printed circuit board.

10. The system of claim 1, wherein the high-power chip generates at least 10 W of heat during normal operation and the low-power chip generates less than 5 W of heat during normal operation.

11. A integrated circuit system, comprising:
a first substrate, comprising:
a top insulation layer disposed on a top surface of the first substrate;
a bottom insulation layer disposed on a bottom surface of the first substrate, the top insulation layer being parallel to the bottom insulation layer;
a high-power chip disposed between and in electrical communication with the top insulation layer and the bottom insulation layer; and
a molding material substantially filled within a space surrounding the high-power chip, the molding material being disposed between the top insulation layer and the bottom insulation layer;
a second substrate disposed adjacent to a first side of the first substrate, the first substrate and the second substrate are in electrical communication with each other; and
a low-power chip disposed on the second substrate.

12. The system of claim 11, further comprising:
a top redistribution feature embedded in the top insulation layer; and
a bottom redistribution feature embedded in the bottom insulation layer,
wherein the top and bottom redistribution features are configured to facilitate routing of electrical signals between the low-power chip and the high-power chip.

13. The system of claim 12, wherein the top redistribution feature and the bottom redistribution feature each comprises one or more electrical conductive wires laterally extended a desired length in a plane parallel to the top surface of the first substrate.

14. The system of claim 12, wherein the top redistribution feature and the bottom redistribution feature each comprises two or more coplanar or non-coplanar electrical conductive wires.

15. The system of claim 11, wherein the molding material further comprising:
one or more heat distribution features formed through the molding material, wherein the heat distribution feature is in physical and thermal contact with the top redistribution feature and the bottom redistribution feature, respectively.

16. The system of claim 15, wherein the one or more heat distribution features are in a form of thermal conductive vias, a thermal conductive sheet, or both.

17. The system of claim 15, wherein the one or more heat distribution features are made of an electrical conductive material comprising copper, aluminum, gold, silver, or alloys of two or more electrical conductive elements.

18. The system of claim 11, further comprising:
a printed circuit board disposed adjacent to a second side of the first substrate, wherein the second side is parallel to and opposing the first side of the first substrate

19. The system of claim 18, wherein the high-power chip is in thermal and electrical communication with the printed circuit board.

20. The system of claim 11, wherein the high-power chip generates at least 10 W of heat during normal operation and the low-power chip generates less than 5 W of heat during normal operation.
